(19) United States
(12) Patent Application Publication
(10) Pub. No.: US 2024/0084437 A1
(43) Pub. Date: Mar. 14, 2024

(54) LAMINATES AND METHODS OF MAKING THE SAME

(71) Applicant: CORNING INCORPORATED, CORNING, NY (US)

(72) Inventors: Young Suk Lee, Seoul (KR); Hyung Soo Moon, Seoul (KR); Seong-ho Seok, Seoul (KR)

(21) Appl. No.: 18/263,419

(22) PCT Filed: Feb. 9, 2022
(86) PCT No.: PCT/US2022/015734

§ 371 Date: Jul. 28, 2023

(30) Foreign Application Priority Data
Feb. 22, 2021 (KR) 10-2021-0023399

(51) Int. Cl. C23C 14/08; C23C 14/14; C23C 14/58; C23C 28/00

(52) U.S. Cl. CPC C23C 14/083; C23C 14/14; C23C 14/5806; C23C 28/3455

(57) ABSTRACT

A laminate can comprise an oxide disposed over a first major surface of a substrate. The oxide layer can comprise a thickness of about 40 nanometers or less. The oxide layer can comprise oxygen and a first element. The first element can comprise at least one of titanium, tantalum, silicon, or aluminum. The oxide layer can comprise an atomic ratio of oxygen to the another element of about 1.5 or less. The laminate can comprise a peel strength between the substrate and the oxide layer of about 1.3 Newtons per centimeter or more. Methods of making a laminate can comprise providing a substrate comprising a first major surface and depositing an oxide layer over the first major surface of the substrate by sputtering from an elemental target comprising an another element in an oxygen environment.

### CROSS REFERENCE TO RELATED APPLICATIONS

This application claims the benefit of priority under 35 U.S.C. § 119 of Korean Patent Application Serial No. 10-2021-0023399 filed on Feb. 22, 2021, the content of which is relied upon and incorporated herein by reference in its entirety.

### FIELD

The present disclosure relates generally to a laminate and methods of making the same and, more particularly, to a laminate comprising an oxide layer and methods of making the same using sputtering.

### BACKGROUND

Laminates comprising glass materials and/or ceramic materials can be used in photovoltaic applications or display applications, for example, liquid crystal displays (LCDs), electrophoretic displays (EPDs), organic light-emitting diode displays (OLEDs), and plasma display panels (PDPs). Glass sheets are commonly fabricated by a flowing glass-forming material to a forming device whereby a glass web may be formed by a variety of web forming processes, for example, slot draw, float, down-draw, fusion down-draw, rolling, tube drawing, or up-draw. The glass web may be periodically separated into individual glass sheets.

It is known to form laminates using a silicon wafer and an electrically conductive layer deposited thereon. Such laminates can be used as a printed circuit in electronic devices. However, forming such laminates with a substrate comprising a glass material and/or a ceramic material can have poor adhesion between the layers of the laminate, especially when the substrate is smooth (e.g., surface roughness (Ra) of about 3 nanometers (nm) or less, about 0.3 nm or less). Consequently, there is a need to provide a laminate with good adhesion between layers of the laminate when the substrate comprises a glass material and/or a ceramic material.

### SUMMARY

The following presents a simplified summary of the disclosure to provide a basic understanding of some embodiments described in the detailed description.

Embodiments of the disclosure can provide laminates with good adhesion between a substrate and an oxide layer. Providing an oxide layer comprising oxygen and a first element with a limited atomic ratio of oxygen to the first element (e.g., about 1.5 or less, about 1 or less, about 0.8 or less) can enable good adhesion. In some embodiments, providing a non-stoichiometric ratio of oxygen to the first element can further promote adhesion. Limiting the thickness of the oxide layer (e.g., about 40 nm or less, about 30 nm or less) can enable good adhesion, for example, by limiting the oxygen content of the oxide layer. In some embodiments, a substrate comprising glass and/or ceramic can have good adhesion with the oxide layer, for example, with covalent bonding or polar interactions. In further embodiments, the first element in the oxide layer can comprise at least one of titanium, tantalum, silicon, or aluminum, which can promote adhesion with the substrate comprising glass and/or ceramic.

In some embodiments, the laminate can comprise a metallic layer disposed over the oxide layer. Providing a metallic layer can enable good adhesion between the metallic layer and the oxide layer. In further embodiments, adhesion between the metallic layer and the oxide layer can be greater than the adhesion between the oxide layer and the substrate. For example, the metallic layer can comprise copper, which has negative mixing enthalpy with titanium in an oxide layer comprising titanium oxide, providing strong adhesion between the metallic layer and the oxide layer. In further embodiments, the metallic layer can be electrically conductive and patterned to form a discontinuous layer over a first major surface of the substrate, which can serve as wiring connections, for example, as part of the circuit board. In even further embodiments, the oxide layer can be electrically non-conductive, which can electrically isolate discontinuous portions of the metallic layer from one another.

Embodiments of the disclosure can provide methods of making a laminate comprising depositing an oxide layer over a substrate using reactive sputtering from an elemental target in an oxygen-containing environment, which can enable control of the oxygen content of the resulting oxide layer and promote adhesion between the substrate and the oxide layer. In some embodiments, a metallic layer (e.g., electrically conductive) can be disposed on the oxide layer (e.g., electrically non-conductive) and patterned to be discontinuous over a first major surface without removing corresponding portions of the discontinuous metallic layer, which can simplify processing of the laminate, for example, by reducing processing time and overall cost to make the laminate.

In some embodiments, a laminate can comprise a substrate comprising a first major surface. The laminate can comprise an oxide layer that can be disposed over the first major surface of the substrate. The oxide layer can comprise a thickness of about 40 nanometers (nm) or less. The oxide layer can comprise oxygen and a first element. The first element can comprise at least one of titanium, tantalum, silicon, or aluminum. The oxide layer can further comprise an atomic ratio of oxygen to the first element that can be about 1.5 or less. A peel strength of the laminate between the substrate and the oxide layer, measured at 20° C. in accordance with IPC-TM-650.2.4.8 Condition A, can be about 1.3 Newtons per centimeter (N/cm) or more.

In further embodiments, the laminate can further comprise a metallic layer disposed over the oxide layer.

In even further embodiments, the metallic layer can comprise copper.

In even further embodiments, the metallic layer comprises a thickness that can be in a range from about 100 nanometers to about 20 micrometers (μm).

In still further embodiments, a thickness of the metallic layer can be in a range from about 2 micrometers to about 15 micrometers.

In even further embodiments, the metallic layer can directly contact the oxide layer.

In even further embodiments, the metallic layer can be discontinuous over the first major surface of the substrate.

In still further embodiments, the oxide layer can be substantially continuous over the first major surface of the substrate.

In further embodiments, the atomic ratio of oxygen to the first element can be about 0.8 or less.

In further embodiments, the oxide layer can comprise titanium oxide. The first element can comprise titanium. An atomic ratio of oxygen to the titanium can be about 1.5 or less.

In even further embodiments, the atomic ratio of oxygen to the titanium of the titanium oxide can be about 0.8 or less.

In further embodiments, the oxide layer can consist essentially of titanium oxide.

In further embodiments, the oxide layer can be electrically non-conductive.

In further embodiments, the thickness of the oxide layer can be in a range from about 10 nanometers to about 30 nanometers.

In further embodiments, the oxide layer can directly contact the first major surface of the substrate.

In further embodiments, the peel strength of the laminate between the substrate and the oxide layer can be in a range from about 2.5 Newtons per centimeter to about 7 Newtons per centimeter.

In further embodiments, the peel strength of the laminate between the substrate and the oxide layer can be about 4 Newtons per centimeter or more.

In further embodiments, the substrate can comprise a glass material.

In further embodiments, the substrate can comprise a ceramic material.

In further embodiments, the substrate comprises a thickness that can be in a range from about 25 micrometers to about 2 millimeters.

In some embodiments, a method of making a laminate can comprise depositing an oxide layer over a first major surface of a substrate by sputtering from an elemental target comprising a first element in an oxygen-containing element. The oxide layer comprises a thickness that can be about 40 nanometers (nm) or less. The oxide layer can comprise oxygen and the first element. The first element can comprise at least one of titanium, tantalum, silicon, or aluminum. The oxide layer can further comprise an atomic ratio of the oxygen to the first element that can be about 1.5 or less. A peel strength of the laminate between the substrate and the oxide layer, measured at 20° C. in accordance with IPC-TM-650.2.4.8 Condition A, can be about 1.3 Newtons per centimeter (N/cm) or more.

In further embodiments, the method can further comprise depositing a metallic layer over the oxide layer.

In even further embodiments, the method can further comprise depositing a mask layer with a predetermined pattern on the metallic layer. The method can further comprise etching at least a portion of the metallic layer after depositing the mask layer. The method can further comprise removing the mask layer after the etching.

In still further embodiments, the metallic layer can be discontinuous over the first major surface of the substrate. The oxide layer can be substantially continuous over the first major surface of the substrate.

In even further embodiments, the metallic layer can comprise copper.

In even further embodiments, a thickness of the metallic layer can be in a range from about 2 micrometers (μm) to about 15 micrometers.

In even further embodiments, the metallic layer can directly contact the oxide layer.

In further embodiments, the method can further comprise heating the laminate at a temperature in a range from about 250° C. to about 400° C. for a time in a range from about 15 minutes to about 6 hours.

In further embodiments, the atomic ratio of the oxygen to the first element can be about 0.8 or less.

In further embodiments, the oxide layer can comprise titanium oxide. The first element can comprise titanium. An atomic ratio of the oxygen to the titanium can be about 1.5 or less.

In even further embodiments, the atomic ratio of the oxygen to the titanium of the titanium oxide can be about 0.8 or less.

In further embodiments, the oxide layer can consist essentially of titanium oxide.

In further embodiments, the oxide layer can be electrically non-conductive.

In further embodiments, the thickness of the oxide layer can be in a range from about 10 nanometers to about 30 nanometers.

In further embodiments, the oxide layer can directly contact the first major surface of the substrate.

In further embodiments, the peel strength of the laminate between the substrate and the oxide layer can be in a range from about 2.5 Newtons per centimeter to about 7 Newtons per centimeter.

In further embodiments, the peel strength of the laminate between the substrate and the oxide layer can be about 4 Newtons per centimeter or more.

In further embodiments, the substrate can comprise a glass material.

In further embodiments, the substrate can comprise a ceramic material.

In further embodiments, the substrate comprises a thickness that can be in a range from about 25 micrometers to about 2 millimeters.

Additional features and advantages of the embodiments disclosed herein will be set forth in the detailed description that follows, and in part will be clear to those skilled in the art from that description or recognized by practicing the embodiments described herein, including the detailed description which follows, the claims, as well as the appended drawings. It is to be understood that both the foregoing general description and the following detailed description present embodiments intended to provide an overview or framework for understanding the nature and character of the embodiments disclosed herein. The accompanying drawings are included to provide further understanding and are incorporated into and constitute a part of this specification. The drawings illustrate various embodiments of the disclosure, and together with the description explain the principles and operations thereof.

### BRIEF DESCRIPTION OF THE DRAWINGS

These and other features, aspects, and advantages are better understood when the following detailed description is read with reference to the accompanying drawings, in which:

FIG. 1 schematically illustrates an exemplary embodiment of a laminate in accordance with some embodiments of the disclosure;

FIG. 2 illustrates a plan view of a laminate taken along line 2-2 of FIG. 1 in accordance with some embodiments of the disclosure;

FIG. 3 is a flow chart illustrating example methods of making a laminate in accordance with embodiments of the disclosure;

FIG. 4 schematically illustrate a step in a method of making a laminate in accordance with embodiments of the disclosure;

FIG. 5-6 schematically illustrate laminates and steps in a method of making a laminate in accordance with embodiments of the disclosure;

FIGS. 7-10 schematically illustrate steps in a method of making a laminate in accordance with embodiments of the disclosure; and

FIG. 11 is a schematic plan view of an example electronic device according to some embodiments; and

FIG. 12 is a schematic perspective view of the example electronic device of FIG. 11.

### DETAILED DESCRIPTION

Embodiments will now be described more fully hereinafter with reference to the accompanying drawings in which exemplary embodiments are shown. Whenever possible, the same reference numerals are used throughout the drawings to refer to the same or like parts. However, this disclosure may be embodied in many different forms and should not be construed as limited to the embodiments set forth herein.

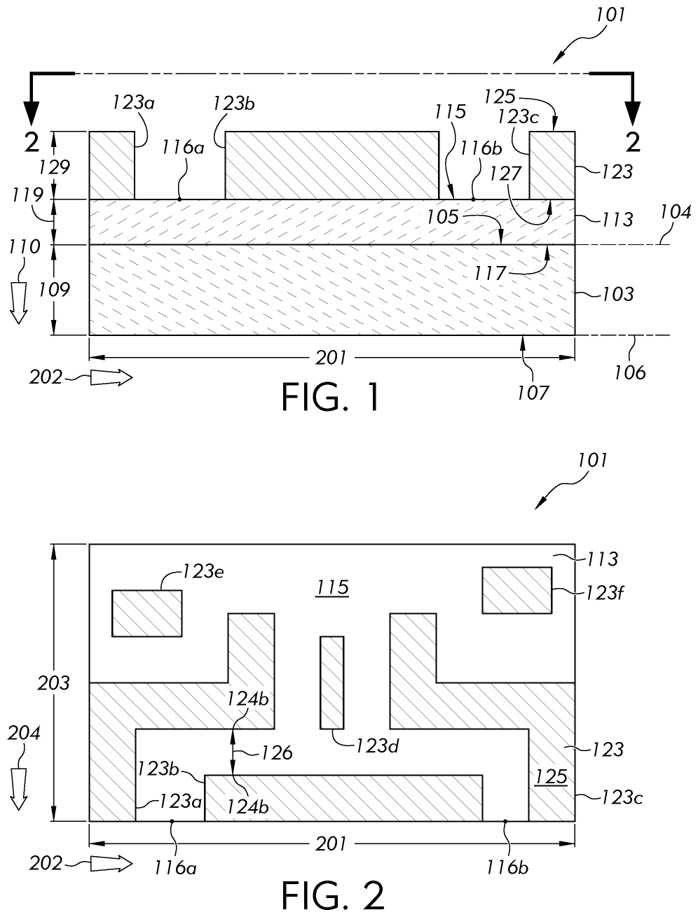

FIGS. 1-2 and 5-6 illustrate views of laminates 101, 501, and 601 comprising a substrate 103 and an oxide layer 113 in accordance with embodiments of the disclosure. In some embodiments, as shown in FIGS. 1-2 and 6, the laminate 101 and 601 can further comprise a metallic layer 123. Unless otherwise noted, a discussion of features of embodiments of one laminate can apply equally to corresponding features of any embodiments of the disclosure. For example, identical part numbers throughout the disclosure can indicate that, in some embodiments, the identified features are identical to one another and that the discussion of the identified feature of one embodiment, unless otherwise noted, can apply equally to the identified feature of any of the other embodiments of the disclosure.

Throughout the disclosure, with reference to FIG. 2, the width 203 of the laminate 101, 501, and/or 601 is considered the dimension of the laminate 101, 501, and/or 601 taken between opposed edges of the laminate in a direction 204 (e.g., a direction 204 of the width 203). Furthermore, throughout the disclosure, the length 201 of the laminate 101, 501, and/or 601 is considered the dimension of the laminate 101, 501, and/or 601 taken between opposed edges of the laminate in a direction 202 (e.g., a direction 202 of the length 201) perpendicular to the direction 204 of the width 203 of the laminate 101, 501, and/or 601. In some embodiments, the width 203 and/or the length 201 of the laminate 101, 501, and 601 and/or the substrate 103 can be about 20 millimeters (mm) or more, about 50 mm or more, about 100 mm or more, about 500 mm or more, about 1,000 mm or more, about 2,000 mm or more, about 3,000 mm or more, or about 4,000 mm or more, although other widths can be provided in further embodiments. In some embodiments, the width 203 and/or the length 201 of the substrate 103 can be in a range from about 20 mm to about 4,000 mm, from about 50 mm to about 4,000 mm, from about 100 mm to about 4,000 mm, from about 500 mm to about 4,000 mm, from about 1,000 mm to about 4,000 mm, from about 2,000 mm to about 4,000 mm, from about 3,000 mm to about 4,000 mm, from about 20 mm to about 3,000 mm, from about 50 mm to about 3,000 mm, from about 100 mm to about 3,000 mm, from about 500 mm to about 3,000 mm, from about 1,000 mm to about 3,000 mm, from about 2,000 mm to about 3,000 mm, from about 2,000 mm to about 2,500 mm, or any ranges or subranges therebetween.

Laminates 101, 501, and 601 of the disclosure comprise the substrate 103. In some embodiments, the substrate 103 can comprise a substrate comprising a glass material and/or a ceramic material. In further embodiments, the substrate can comprise a pencil hardness of 8H or more, for example, 9H or more. As used herein, pencil hardness is measured using ASTM D 3363-20 with standard lead graded pencils. In further embodiments, the substrate 103 can consist essentially of a glass material or consist entirely of a glass material. In further embodiments, the substrate 103 can consist essentially of or consist entirely of a ceramic material. In some embodiments, the substrate 103 can comprise an oxide-containing material and/or a silicon-containing material.

In some embodiments, the substrate 103 can comprise a glass material. As used herein, “glass” refers to an amorphous material comprising at least 30 mole percent (mol %) of silica (SiO₂). A substrate comprising glass (e.g., a glass material) includes both glasses and glass-ceramics, wherein glass-ceramics have one or more crystalline phases and an amorphous, residual glass phase. A substrate comprising glass comprises an amorphous material (e.g., glass) and optionally one or more crystalline materials (e.g., ceramic). Amorphous materials and glass may be strengthened. As used herein, the term “strengthened” may refer to a material that has been chemically strengthened, for example, through ion-exchange of larger ions for smaller ions in the surface of the substrate. However, other strengthening methods, for example, thermal tempering, or utilizing a mismatch of the coefficient of thermal expansion between portions of the substrate to create compressive stress and central tension regions, may be utilized to form strengthened substrates. Exemplary glass materials, which may be free of lithia or not, comprise soda-lime glass, alkali aluminosilicate glass, alkali-containing borosilicate glass, alkali-containing aluminoborosilicate glass, alkali-containing phosphosilicate glass, and alkali-containing aluminophosphosilicate glass. Glass materials can comprise an alkali-containing glass or an alkali-free glass, either of which may be free of lithia or not. In one or more embodiments, glass materials may comprise, in mole percent (mol %). SiO₂ in a range from about 40 mol % to about 80%, Al₂O₃ in a range from about 5 mol % to about 30 mol %, B₂O₃ in a range from 0 mol % to about 10 mol %, ZrO₂ in a range from 0 mol % to about 5 mol %, P₂O₅ in a range from 0 mol % to about 15 mol %, TiO₂ in a range from 0 mol % to about 2 mol %, R₂O in a range from 0 mol % to about 20 mol %, and RO in a range from 0 mol % to about 15 mol %. As used herein, R₂O can refer to an alkali metal oxide, for example, Li₂O, Na₂O, K₂O, Rb₂O, Cs₂O, or combinations thereof. As used herein, RO can refer to MgO, CaO, SrO, BaO, ZnO, or combinations thereof. In some embodiments, glass materials may optionally further comprise in a range from 0 mol % to about 2 mol % of each of Na₂SO₄, NaCl, NaF, NaBr, K₂SO₄, KCl, KF, KBr, As₂O₃, Sb₂O₃, SnO₂, Fe₂O₃, MnO, MnO₂, MnO₃, Mn₂O₃, Mn₃O₄, and/or Mn₂O₇. “Glass-ceramics” include materials produced through controlled crystallization of glass. In some embodiments, glass-ceramics can comprise about 1% to about 99% crystallinity. Examples of suitable glass-ceramics may include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. Glass-ceramic substrates may be strengthened using chemical strengthening processes. In one or more embodiments, MAS-System glass-ceramic substrates may be strengthened in a Li₂SO₄ molten salt, whereby an exchange of 2Li⁺ for Mg²⁺ can occur.

In some embodiments, the substrate 103 can comprise a ceramic material. As used herein, “ceramic” refers to a crystalline phase. A substrate comprising ceramic (e.g., a ceramic material) includes both ceramics and glass-ceramics, wherein glass-ceramics have one or more crystalline phases and an amorphous, residual glass phase. Ceramic materials may be strengthened (e.g., chemically strengthened). In some embodiments, a ceramic material can be formed by heating a substrate comprising a glass material to form ceramic (e.g., crystalline) portions. In further embodiments, ceramic materials may comprise one or more nucleating agents that can facilitate the formation of crystalline phase(s). In some embodiments, the ceramic materials can comprise one or more oxides, nitrides, oxynitrides, carbides, borides, and/or silicides. Example embodiments of ceramic oxides include zirconia (ZrO₂), zircon (ZrSiO₄), an alkali metal oxide (e.g., sodium oxide (Na₂O)), an alkali earth metal oxide (e.g., magnesium oxide (MgO)), titania (TiO₂), hafnium oxide (Hf₂O), yttrium oxide (Y₂O₃), iron oxides, beryllium oxides, vanadium oxide (VO₂), fused quartz, mullite (a mineral comprising a combination of aluminum oxide and silicon dioxide), and spinel (MgAl₂O₄). Example embodiments of ceramic nitrides include silicon nitride (Si₃N₄), aluminum nitride (AlN), gallium nitride (GaN), beryllium nitride (Be₃N₂), boron nitride (BN), tungsten nitride (WN), vanadium nitride, alkali earth metal nitrides (e.g., magnesium nitride (Mg₃N₂)), nickel nitride, and tantalum nitride. Example embodiments of oxynitride ceramics include silicon oxynitride, aluminum oxynitride, and a SiAlON (a combination of alumina and silicon nitride and can have a chemical formula, for example, Si₁₂₋ₘ₋ₙAlₘ₊ₙOₙNi₆₋ₙ, Si₆₋ₙAlₙOₙN₈₋ₙ, or Si₂₋ₙAlₙO₁₊ₙN₂₋ₙ, where m, n, and the resulting subscripts are all non-negative integers). Example embodiments of carbides and carbon-containing ceramics include silicon carbide (SiC), tungsten carbide (WC), an iron carbide, boron carbide (B₄C), alkali metal carbides (e.g., lithium carbide (Li₄C₃)), alkali earth metal carbides (e.g., magnesium carbide (Mg₂C₃)), and graphite. Example embodiments of borides include chromium boride (CrB₂), molybdenum boride (Mo₂B₅), tungsten boride (W₂B₅), iron boride, titanium boride, zirconium boride (ZrB₂), hafnium boride (HfB₂), vanadium boride (VB₂), Niobium boride (NbB₂), and lanthanum boride (LaB₆). Example embodiments of silicides include molybdenum disilicide (MoSi₂), tungsten disilicide (WSi₂), titanium disilicide (TiSi₂), nickel silicide (NiSi), alkali earth silicide (e.g., sodium silicide (NaSi)), alkali metal silicide (e.g., magnesium silicide (Mg₂Si)), hafnium disilicide (HfSi₂), and platinum silicide (PtSi).

As used herein, a silicon-containing material means a material comprising at least 30 mole percent (mol %) of silicon (Si). As described above, silicon can be found in both glass materials and ceramic materials in coordination with other elements, for example, oxygen, nitrogen, carbon, aluminum, hafnium, magnesium, molybdenum, nickel, platinum, sodium, titanium, tungsten, and/or zirconium. As used herein, an oxygen-containing material means a material comprising at least 15 mole percent (mol %) of oxygen (O). As described above, oxygen can be found in both glass materials and ceramic materials in coordination with other elements, for example, alkali metals, alkali earth metals, transition metals, aluminum, bismuth, carbon, gallium, lead, nitrogen, phosphorous, silicon, sulfur, selenium, and/or tin.

Throughout the disclosure, an elastic modulus (e.g., Young's modulus) of the substrate 103 (e.g., glass material, ceramic material, silicon-containing material, oxygen-containing material) and/or the oxide layer 113 is measured using indentation methods in accordance with ASTM E2546-15. In some embodiments, the substrate 103 can comprise an elastic modulus of about 10 GigaPascals (GPa) or more, about 50 GPa or more, about 60 GPa or more, about 70 GPa or more, about 100 GPa or less, or about 80 or less. In some embodiments, the substrate 103 can comprise an elastic modulus in a range from about 10 GPa to about 100 GPa, from about 50 GPa to about 100 GPa, from about 50 GPa to about 80 GPa, from about 60 GPa to about 80 GPa, from about 70 GPa ta about 80 GPa, or any range or subrange therebetween.

In some embodiments, the substrate 103 can be optically transparent. As used herein, “optically transparent” or “optically clear” means an average transmittance of 70% or more in the wavelength range of 400 nm to 700 nm through a 1.0 mm thick piece of a material. In some embodiments, an “optically transparent material” or an “optically clear material” may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by averaging transmittance measurements of whole number wavelengths from about 400 nm to about 700 nm.

As shown in FIGS. 1 and 5-6, the substrate 103 can comprise a first major surface 105 and a second major surface 107 opposite the first major surface 105. As shown in FIG. 1, the first major surface 105 can extend along a first plane 104. The second major surface 107 can extend along a second plane 106. In some embodiments, as shown, the second plane 106 can be parallel to the first plane 104. As used herein, a substrate thickness can be defined between the first major surface 105 and the second major surface 107 as a distance between the first plane 104 and the second plane 106. In some embodiments, as shown in FIG. 1, the substrate thickness 109 can be measured in a direction 110 perpendicular to the direction 202 of the length 201 and the direction 204 of the width 203. In some embodiments, the substrate thickness 109 can be about 10 micrometers (μm) or more, about 25 μm or more, about 40 μm or more, about 60 μm or more, about 80 μm or more, about 100 μm or more, about 125 μm or more, about 150 μm or more, about 3 millimeters (mm) or less, about 2 mm or less, about 1 mm or less, about 800 μm or less, about 500 μm or less, about 300 μm or less, about 200 μm or less, about 180 μm or less, or about 160 μm or less. In some embodiments, the substrate thickness 109 can be in a range from about 10 μm to about 3 mm, from about 10 μm to about 2 mm, from about 25 μm to about 2 mm, from about 40 μm to about 2 mm, from about 60 μm to about 2 mm, from about 80 μm to about 2 mm, from about 100 μm to about 2 mm, from about 100 μm to about 1 mm, from about 100 μm to about 800 μm, from about 100 μm to about 500 μm, from about 125 μm to about 500 μm, from about 125 μm to about 300 μm, from about 125 μm to about 200 μm, from about 150 μm to about 200 μm, from about 150 μm to about 160 μm, or any range or subrange therebetween. In some embodiments, the substrate thickness 109 can be in a range from about 80 μm to about 2 mm, from about 80 μm to about 1 mm, from about 80 μm to about 500 μm, from about 80 μm to about 300 μm, from about 200 μm to about 2 mm, from about 200 μm to about 1 mm, from about 200 μm to about 500 μm, from about 500 μm to about 2 mm, from about 500 μm to about 1 mm, or any range or subrange therebetween.

The first major surface 105 of the substrate 103 can comprise a surface roughness (Ra). Throughout the disclosure, all surface roughness values set forth in the disclosure are a surface roughness (Ra) calculated using an arithmetical mean of the absolute deviations of a surface profile from an average position in a direction normal to the surface of a test area of 10 μm by 10 μm as measured using atomic force microscopy (AFM). In some embodiments, the surface roughness (Ra) of the first major surface 105 and/or the second major surface 107 of the substrate 103 can be about 5 nm or less, about 3 nm or less, about 2 nm or less, about 1 nm or less, about 0.9 nm or less, about 0.5 nm or less, or about 0.3 nm or less. In some embodiments, the surface roughness (Ra) of the first major surface 105 and/or the second major surface 107 of the substrate 103 can be in a range from about 0.1 nm to about 5 nm, from about 0.1 nm to about 3 nm, from about 0.1 nm to about 2 nm, from about 0.1 nm to about 1 nm, from about 0.1 nm to about 0.9 nm, from about 0.1 nm to about 0.5 nm, from about 0.1 nm to about 0.3 nm, from about 0.15 nm to about 5 nm, from about 0.15 nm to about 3 nm, from about 0.15 nm to about 2 nm, from about 0.15 nm to about 1 nm, from about 0.15 nm to about 0.9 nm, from about 0.15 nm to about 0.5 nm, from about 0.15 nm to about 0.3 nm, from about 0.2 nm to about 5 nm, from about 0.2 nm to about 3 nm, from about 0.2 nm to about 2 nm, from about 0.2 nm to about 1 nm, from about 0.2 nm to about 0.9 nm, from about 0.2 nm to about 0.5 nm, from about 0.2 nm to about 0.3 nm, or any range or subrange therebetween.

As shown in FIGS. 1-2 and 5-6, the laminate 101, 501, and 601 comprises the oxide layer 113 that can comprise a third major surface 115 and a fourth major surface 117 opposite the third major surface 115. In some embodiments, the third major surface 115 can extend along a third plane. In some embodiments, as shown, the fourth major surface 117 can extend along a fourth plane. In some embodiments, as shown in FIGS. 1 and 5-6, the third major surface 115 can be parallel to the fourth major surface 117. As used herein, a thickness 119 of the oxide layer 113 can be defined between the third major surface 115 and the fourth major surface 117 as a distance between the third plane and the fourth plane averaged over the first major surface 105 of the substrate 103. In some embodiments, as shown in FIG. 1, the thickness 119 of the oxide layer 113 can be measured in the direction 110 (e.g., perpendicular to the direction 202 of the length 201 and the direction 204 of the width 203, the same direction as the substrate thickness 109). As used herein, the thickness 119 of the oxide layer 113 is measured using a scanning electron microscope (SEM) of a cross-section similar to that shown in FIG. 1. In some embodiments, the thickness 119 of the oxide layer 113 can be about 1 nanometer (nm) or more, about 5 nm or more, about 10 nm or more, about 15 nm or more, about 20 nm or more, about 25 nm or more, about 40 nm or less, about 35 nm or less, or about 30 nm or less. In some embodiments, the thickness 119 of the oxide layer 113 can be in a range from about 1 nm to about 40 nm, from about 5 nm to about 40 nm, from about 5 nm to about 35 nm, from about 10 nm to about 35 nm, from about 10 nm to about 30 nm, from about 15 nm to about 30 nm, from about 20 nm to about 30 nm, from about 25 nm to about 30 nm, or any range or subrange therebetween.

As shown in FIGS. 1 and 5-6, the oxide layer 113 can be disposed over the first major surface 105 of the substrate 103. In some embodiments, as shown, the fourth major surface 117 of the oxide layer 113 can face the first major surface 105 of the substrate 103. In further embodiments, as shown, the oxide layer 113 can directly contact the substrate 103, for example, by the fourth major surface 117 of the oxide layer 113 directly contacting the first major surface 105 of the substrate 103. In some embodiments, as shown in FIGS. 1 and 5-6, the oxide layer 113 can be substantially continuous and/or continuous over the first major surface 105 of the substrate 103. As used herein, “continuous” means that each pair of points on the surface of the layer comprising the material of the layer is connected by a path running entirely through the material of the layer. For example, as shown in FIGS. 1-2, a first point 116a and a second point 116b on the third major surface 115 of the oxide layer 113 is connected by a path (e.g., running in the direction 202 from the first point 116a to the second point 116b) running entirely through the material of the oxide layer 113, and all such pairs of points on the third major surface 115 of the oxide layer 113 are connected by a path running entirely through the material of the oxide layer 113. As used herein, “substantially continuous” means that the material would be continuous but for a separation of about 10 nanometers or less between portions of the layer preventing a path connecting a pair of points from running entirely through the material of the layer. In some embodiments, the separation of about 10 nanometers or less in a substantially continuous oxide layer 113 can be a manufacturing defect, for example, variability of a sputtered oxide layer and/or variability in the amount of material removed during an etching step (e.g., etching the metallic layer deposited on the oxide layer). In some embodiments, as shown in FIG. 1, the oxide layer 113 can be a monolithic layer and/or a substantially monolithic layer that seamlessly extends over the entire first major surface 105 of the substrate 103. As used herein, the oxide layer 113 is monolithic if the material of the oxide layer 113 is coextensive with the area of the first major surface 105 of the substrate 103 with no gaps in the oxide layer 113. As used herein, the oxide layer 113 is substantially monolithic if the oxide layer would be monolithic over the first major surface 105 of the substrate 103 but for a border around the periphery of the first major surface 105 not covered by the oxide layer 113 and/or manufacturing defects within the material of the oxide layer 113 with each manufacturing defect comprising an area over the first major surface 105 of the substrate 103 of about 10,000 nanometers squared (nm²) or less.

The oxide layer 113 comprises an oxide comprising oxygen and a first element. In some embodiments, the first element comprises at least one of titanium, tantalum, silicon, or aluminum. For example, the oxide layer 113 can comprise titanium oxide, tantalum oxide, silicon oxide, and/or aluminum oxide. In further embodiments, the oxide layer 113 consists essentially of one or more oxides. In further embodiments, the oxide layer 113 can consist essentially of titanium oxide. In further embodiments, the oxide layer 113 can consist essentially of tantalum oxide. In further embodiments, the oxide layer 113 can consist essentially of silicon oxide. In further embodiments, the oxide layer 113 can consist essentially of aluminum oxide.

The oxide layer 113 can comprise an atomic ratio of oxygen to the first element. As used herein, the atomic ratio of an oxide layer refers to the amount of oxygen in the oxide layer in atomic percent (atomic %) divided by the amount of the first element in the oxide layer in atomic %. Likewise, the atomic ratio of a specific oxide comprising oxygen and the first element refers to the amount of oxygen in the specific oxide in atomic percent (atomic %) divided by the amount of the first element in the specific oxide in atomic %. Without wishing to be bound by theory, the oxide layer can comprise the oxide that can comprise a non-stoichiometric ratio of oxygen to the first element. As used herein, an oxide with a non-stoichiometric ratio refers to an oxide where the ratio between oxygen and the first element cannot be expressed using integers between 1 and 5. Without wishing to be bound by theory, the oxide layer can comprise an oxide (e.g., comprising a non-stoichiometric ratio of oxygen to the first element) that does not correspond to a naturally occurring oxide (e.g., titania, alumina, silica), for example, through a partial (e.g., incomplete) reaction between the first element and oxygen. Without wishing to be bound by theory, limiting the atomic ratio of oxygen to the first element can increase adhesion with a substrate comprising a glass material, a ceramic material, an oxygen-containing material, and/or a silicon-containing material by promoting bonding between the oxide and the substrate and/or intermolecular interactions between the oxide and the substrate. For example, an oxide with a limited atomic ratio of oxygen to the first element can comprise an energetically unstable or metastable configuration (e.g., coordination number), which may encourage interaction with material at the first major of the substrate.

In some embodiments, the atomic ratio of the oxide layer 113 can be about 1.5 or less, about 1.3 or less, about 1.1 or less, about 1.0 or less, about 0.9 or less, about 0.8 or less, about 0.6 or less, about 0.5 or less, or about 0.4 or less, about 0.1 or more, about 0.25 or more, about 0.35 or more, about 0.5 or more, about 0.7 or more, about 1.0 or more or about 1.1 or more. In some embodiments, the atomic ratio of the oxide layer 113 can be in a range from about 0.1 to about 1.5, from about 0.25 to about 1.5, from about 0.35 to about 1.5, from about 0.5 to about 1.5, from about 0.7 to about 1.5, from about 1.0 to about 1.5, from about 1.1 to about 1.5, from about 1.1 to about 1.3, or any range or subrange therebetween. In some embodiments, the atomic ratio of the oxide layer 113 can be in a range from about 0.1 to about 1.3, from about 0.25 to about 1.3, from about 0.35 to about 1.3, from about 0.5 to about 1.3, from about 0.5 to about 1.0, from about 0.5 to about 0.9, from about 0.7 to about 0.9, from about 0.7 to about 0.8, or any range or subrange therebetween. In some embodiments, the atomic ratio of the oxide layer 113 can be in a range from about 0.1 to about 1.1, from about 0.1 to about 1.0, from about 0.1 to about 0.9, from about 0.1 to about 0.8 from about 0.25 to about 0.8, from about 0.25 to about 0.6, from about 0.35 to about 0.6, from about 0.35 to about 0.5, from about 0.35 to about 0.4, or any range subrange therebetween.

In some embodiments, the oxide layer 113 can consist essentially of titanium oxide. In further embodiments, an atomic ratio of the titanium oxide can be about 1.5 or less. For example, titanium oxide can comprise titanium(II) oxide (TiO), titanium (III) oxide (Ti₂O₃), dititanium oxide (Ti₂O), trititanium oxide (Ti₃O), and/or a non-stoichiometric form of titanium oxide instead of titania (TiO₂). In even further embodiments, the atomic ratio of the titanium oxide can be about 0.8 or less (e.g., Ti₂O, Ti₃O, or a non-stoichiometric form of titanium oxide).

In some embodiments, the oxide layer 113 can be electrically non-conductive. As used herein, “electrically non-conductive” refers to a material with an electrical conductivity of about 100 Siemens per meter (S/m) or less (i.e., an electrical resistivity of about 0.01 Ohm meters (Q m) or more). Unless otherwise specified, electrical conductivity is measured at 20° C. in accordance with ASTM 1004-17.

In further embodiments, the oxide layer can comprise an electrical conductivity of about 10 S/m or less, about 1 S/m or less, about 0.1 S/m or less, about 10⁻³ S/m or less, about 10⁻²⁰ S/m or more, about 10⁻¹⁸ S/m or more, about 10⁻¹² S/m or more, or about 10⁻⁶ S/m or more. In further embodiments, the oxide layer can comprise an electrical conductivity in a range from about 10⁻²⁰ S/m to about 100 S/m, from about 10⁻¹⁸ S/m to about 10 S/m, from about 10⁻¹⁸ S/m to about 1 S/m, from about 10⁻¹² S/m to about 1 S/m, from about 10⁻¹² S/m to about 0.1 S/m, from about 10⁻⁶ S/m to about 0.1 S/m, from about 10⁻⁶ S/m to about 10⁻³ S/m, or any range or subrange therebetween.

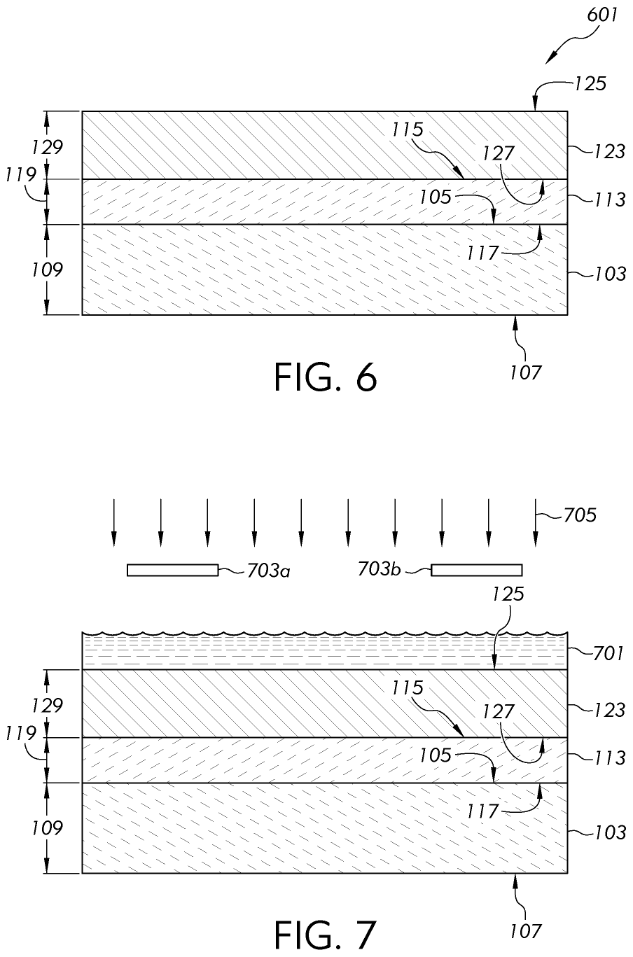

In some embodiments, as shown in FIGS. 1-2 and 6, the laminate 101 and 601 can comprise a metallic layer 123 disposed over the oxide layer 113. In further embodiments, as shown in FIGS. 1 and 6, the metallic layer 123 can comprise a fifth surface area 125 and a sixth surface area 127 opposite the fifth surface area 125. In even further embodiments, the metallic layer 123 can comprise a thickness 129 defined between the fifth surface area 125 and the sixth surface area 127 as the average distance between the fifth surface area 125 and the sixth surface area 127. In still further embodiments, as shown in FIG. 1, the thickness 129 of metallic layer 123 can be measured in the direction 110 (e.g., perpendicular to the direction 202 of the length 201 and the direction 204 of the width 203, the same direction as the substrate thickness 109 and/or the thickness 119 of the oxide layer 113). In still further embodiments, the thickness 129 can be about 100 nm or more, about 500 nm or more, about 1 μm or more, about 2 μm or more, about 5 μm or more, about 20 μm or less, about 18 μm or less, about 15 μm or less, about 12 μm or less, or about 10 μm or less. In still further embodiments, the thickness 129 can be in a range from about 100 nm to about 20 μm, from about 500 nm to about 20 μm, from about 500 nm to about 18 μm, from about 1 μm to about 18 μm, from about 1 μm to about 15 μm, from 2 μm to about 15 μm, from about 2 μm to about 12 μm, from about 5 μm to about 12 μm, from about 5 μm to about 10 μm, or any range or subrange therebetween.

In some embodiments, as shown in FIGS. 1 and 6, sixth surface area 127 of the metallic layer 123 can face the third major surface 115 of the oxide layer 113. In further embodiments, as shown, the metallic layer 123 can directly contact the oxide layer 113, for example, by the sixth surface area 127 of the metallic layer 123 directly contacting the third major surface 115 of the oxide layer 113. In some embodiments, as shown in FIGS. 1-2, the metallic layer 123 can be discontinuous over the first major surface 105 of the substrate 103. As used herein, a layer is discontinuous when a first portion of a layer is not connected to a second portion of the layer by a path running through the material of the layer, and the minimum distance between portions is about 20 nanometers or more measured over the first major surface of the substrate. For example, as shown in FIGS. 1 and 2, the metallic layer 123 is discontinuous over the first major surface of substrate 103 because a first portion 123a of the metallic layer 123 is not connected to a second portion 123b of the metallic layer 123 by a path running through the material of the metallic layer 123, and a minimum distance 126 between first portion 123a and the second portion 123b measured between the pair of points 124a and 124b is about 20 nanometers or more. Likewise, as shown, the first portion 123a of the metallic layer is not connected to the third portion 123c, and the second portion 123b is not connected to the third portion 123c, provided that the corresponding minimum distance is about 20 nanometers or more. In some embodiments, a minimum distance 126 between discontinuous portions (e.g., portions 123a, 123b) of the metallic layer 123 can be about 50 nanometers or more, about 100 nanometers or more, about 500 nanometers or more, about 1 μm or more, or about 10 μm or more. In some embodiments, as shown in FIG. 2, the metallic layer 123 can comprise a plurality of portions 123a-f that are not connected to one another by a path running through the material of the metallic layer 123.

In some embodiments, the metallic layer 123 can comprise a transition metal. In further embodiments, the metallic layer 123 can comprise copper, cobalt, cadmium, chromium, gold, iridium, iron, lead, molybdenum, nickel, platinum, palladium, rhodium, silver, and/or zinc. In even further embodiments, the metallic layer 123 can comprise copper. In still further embodiments, the metallic layer 123 can consist essentially of copper. In some embodiments, the metallic layer 123 can comprise aluminum, beryllium, magnesium, and/or copper. In some embodiments, mixing between the metallic layer 123 and the first element of the oxide layer 113 can be enthalpically favorable (e.g., between titanium as the first element of the oxide layer and copper and the metallic layer).

Metallic layer 123 can have an electrical conductivity of about 10³ Siemens per meter (S/m) or more (i.e., an electrical resistivity of about 10⁻³ Ohm meters (Ω m) or less). In further embodiments, the metallic layer can comprise an electrical conductivity of about 10⁵ S/m or more, about 10⁶ S/m or more, about 10⁷ S/m or more, about 10²⁰ S/m or less, about 10¹⁵ S/m or less, about 10¹² S/m or less, about 10⁹ S/m or less, or about 10⁷ S/m or less. In further embodiments, the metallic layer 123 can comprise an electrical conductivity in a range from about 10³ S/m to about 10²⁰ S/m, from about 10³ S/m to about 10¹⁵ S/m, from about 10⁵ S/m to about 10¹⁵ S/m, from about 10⁶ S/m to about 10¹² S/m, from about 10⁷ S/m to about 10¹² S/m, from about 10⁷ S/m to about 10⁹ S/m, or any range or subrange therebetween.

The laminate 101, 501, and/or 601 can comprise a peel strength. Throughout the disclosure, peel strength is measured at 20° C. in accordance with IPC-TM-650.2.4.8 “Peel Strength of Metallic Clad Laminates” condition A. As used herein, the peel strength of the laminate refers to the peel strength between the substrate (e.g., first major surface) and the oxide layer (e.g., fourth major surface). Without wishing to be bound by theory, the adhesion (e.g., measured as a peel strength) between the substrate and the oxide layer can be weaker than an adhesion between other layers of the laminate (e.g., between the oxide layer and the metallic layer), if provided. In some embodiments, the peel strength can be about 1.3 Newtons per centimeter (N/cm) or more, about 2.5 N/cm or more, about 4 N/cm or more, about 5 N/cm or more, about 12 N/cm or less, about 9 N/cm or less, about 7 N/cm or less, or about 6 N/cm or less. In some embodiments, the peel strength can be in a range from about 1.3 N/cm to about 12 N/cm, from about 1.3 N/cm to about 9 N/cm, from about 2.5 N/cm to about 9 N/cm, from about 2.5 N/cm to about 7 N/cm, from about 4 N/cm to about 7 N/cm, from about 4 N/cm to about 6 N/cm, from about 5 N/cm to about 6 N/cm, or any range or subrange therebetween.

In some embodiments, the laminate 101, 501, and/or 601 of the embodiments of the disclosure can be incorporated into an application (e.g., a display application, an electronic device). For example, the laminate can be used in a wide range of applications comprising liquid crystal displays (LCDs), electrophoretic displays (EPDs), organic light-emitting diode displays (OLEDs), plasma display panels (PDPs), touch sensors, photovoltaics, appliances, or the like. Such displays can be incorporated, for example, into mobile phones, tablets, laptops, watches, wearables, and/or touch-capable monitors or displays. For example, the laminate can be used as a circuit board in a wide range of applications comprising displays, wireless communication, and/or computations, for example, as a circuit board, a processor (e.g., application processor, microprocessor), and/or an antenna (e.g., millimeterWave).

An electronic product, for example a consumer electronic product, may include a housing comprising a front surface, a back surface, and side surfaces; electrical components at least partially within the housing, the electrical components comprising a controller, a memory, and a display, the display at or adjacent the front surface of the housing; and a cover substrate disposed over the display, wherein at least one of a portion of the housing or the cover substrate comprises the laminate described herein.

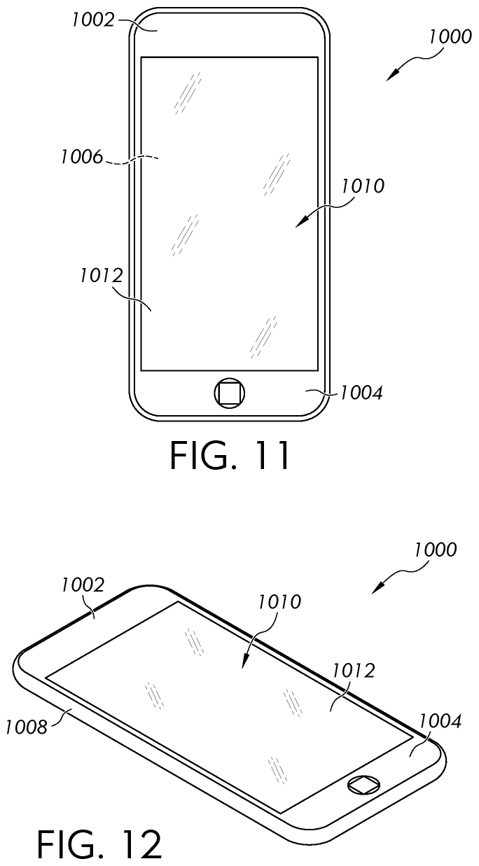

The laminate disclosed herein may be incorporated into another article, for example, an article with a display (or display articles) (e.g., consumer electronics, including mobile phones, tablets, computers, navigation systems, wearable devices (e.g., watches) and the like), architectural articles, transportation articles (e.g., automotive, trains, aircraft, sea craft, etc.), or appliance articles. An exemplary article incorporating any of the laminate disclosed herein is shown in FIGS. 11 and 12. Specifically, FIGS. 11 and 12 show an electronic device 1000 including a housing 1002 having front 1004, back 1006, and side surfaces 1008; electrical components (not shown) that are at least partially inside or entirely within the housing and including at least a controller, a memory, and a display 1010 at or adjacent to the front surface of the housing; and a cover substrate 1012 at or over the front surface of the housing such that it is over the display. In some embodiments, the electrical components or the housing 1002 may include any of the laminates disclosed herein.

In some embodiments, methods of making an electronic product can comprise placing electrical components at least partially within a housing, the housing comprising a front surface, a back surface, and side surfaces, and the electrical components comprising a controller, a memory, and a display, wherein the display is placed at or adjacent the front surface of the housing. The methods can further comprise depositing a cover substrate over the display. At least one of a portion of the electrical components or the housing comprises the laminates manufactured by any of the methods of the disclosure.

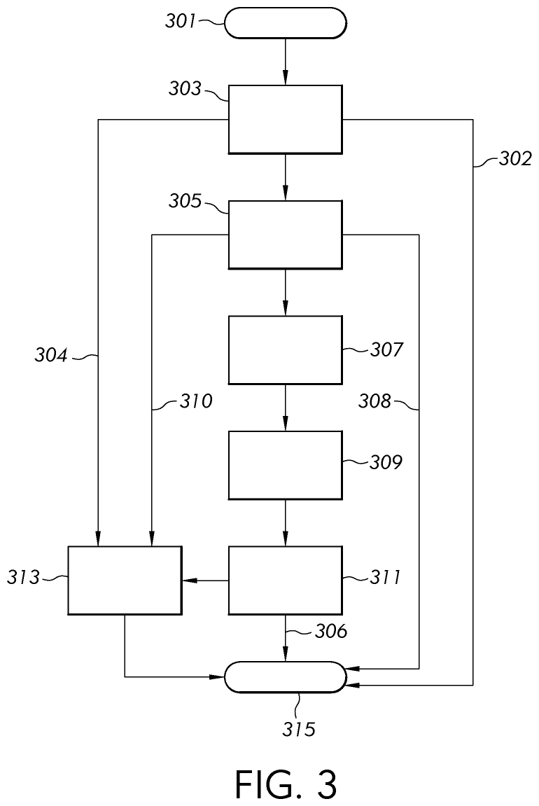

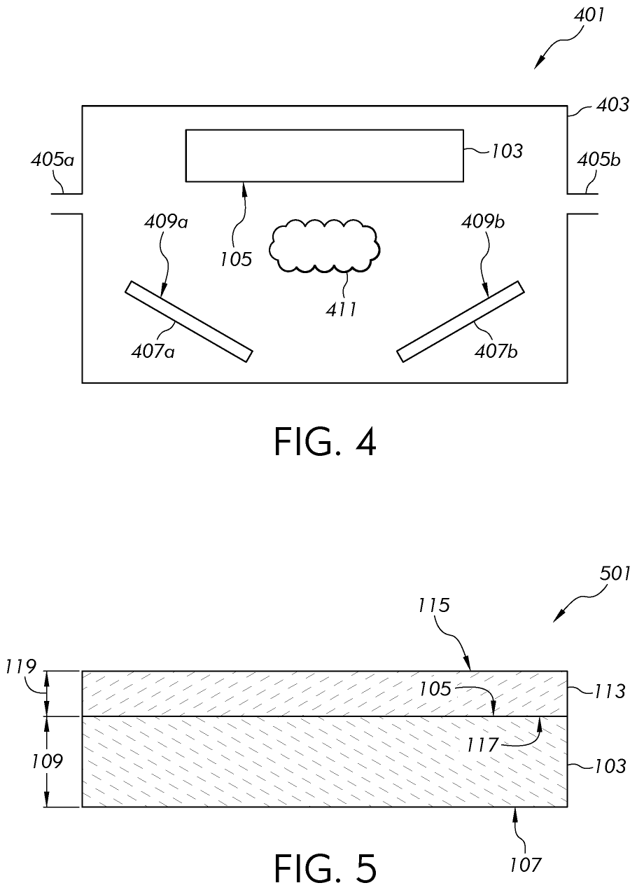

Embodiments of methods of making a laminate in accordance with embodiments of the disclosure will be discussed with reference to the flow chart in FIG. 3 and example method steps illustrated in FIGS. 4-10.

In a first step 301 of methods of the disclosure, methods can start with providing a substrate 103. In some embodiments, the substrate 103 may be provided by purchase or otherwise obtaining a substrate or by forming the substrate. In some embodiments, the substrate 103 can comprise a glass material and/or a ceramic substrate. In further embodiments, glass substrates and/or ceramic substrates can be provided by forming them with a variety of ribbon forming processes, for example, slot draw, down-draw, fusion down-draw, up-draw, press roll, redraw or float. In further embodiments, ceramic substrates can be provided by heating a glass substrate to crystallize one or more ceramic crystals. In further embodiments, the substrate 103 can comprise an oxygen-containing material and/or a silicon-containing material. The substrate 103 may comprise a second major surface 107 (see FIGS. 1 and 5-6) that can extend along a plane. The second major surface 107 can be opposite the first major surface 105.

After step 301, as shown in FIG. 4, methods can proceed to step 303 comprising sputtering from an elemental target 407a, 407b comprising a first element in an oxygen-containing environment. Without wishing to be bound by theory, sputtering comprises ejecting material from a target that is deposited on a substrate. In some embodiments, the sputtering can deposit the oxide layer 113 over the first major surface 105 of the substrate 103, as shown in FIG. 5. In some embodiments, as shown in FIG. 4, the sputtering can occur using a sputtering apparatus 401, for example, in a sputtering chamber 403 comprising an elemental target 407a, 407b positioned opposite the substrate 103. In further embodiments, the elemental target 407a, 407b can comprise one or more elemental target(s), for example, the two elemental targets shown. In further embodiments, as shown, a sputtering surface 409a, 409b of the elemental target 407a, 407b can face the first major surface 105 of the substrate 103. In further embodiments, the elemental target 407a, 407b can comprise the first element corresponding to the first element of the oxide layer to be deposited on the first major surface 105 of the substrate 103. For example, the elemental target 407a, 407b can consist of titanium, tantalum, silicon, or aluminum. As shown in FIG. 4, the material sputtered from the elemental target 407a, 407b can react with oxygen in the oxygen-containing environment, as shown schematically as cloud 411, before being deposited on the first major surface 105 of the substrate 103 as the oxide layer 113.

In further embodiments, as shown, the sputtering chamber 403 can comprise an orifice 405a, 405b that can be used to control an environment in the sputtering chamber 403. In even further embodiments, the orifice 405a, 405b can be used to provide a reduced pressure (e.g., below atmospheric pressure, partial vacuum) within the sputtering chamber. In even further embodiments, the orifice 405a, 405b can be used to provide a continuous flow of gas through the sputtering chamber 403, for example, to maintain a predetermined partial pressure of oxygen within the sputtering chamber 403. In even further embodiments, the environment in the sputtering chamber can comprise oxygen. In still further embodiments, a partial pressure of oxygen in the environment in the sputtering chamber can be about 100 Pascals (Pa) or more, about 200 Pa or more, about 500 Pa or more, about 15,000 Pa or less, about 10,000 Pa or less, about 5,000 Pa or less, or about 2,000 Pa or less. In still further embodiments, a partial pressure of oxygen in the environment in the sputtering chamber can be in a range from about 100 Pa to about 15,000 Pa, from about 100 Pa to about 10,000 Pa, from about 200 Pa to about 10,000 Pa, from about 200 Pa to about 5,000 Pa, from about 500 Pa to about 5,000 Pa, from about 500 Pa to about 2,000 Pa, or any range or subrange therebetween. In still further embodiments, a partial pressure of oxygen in the environment in the sputtering chamber can be about 0.001 Pa or more, about 0.01 Pa or more, about 0.05 Pa or more, about 100 Pa or less, about 10 Pa or less, about 1 Pa or less, or about 0.1 Pa or less. In still further embodiments, a partial pressure of oxygen in the environment in the sputtering chamber can be in a range from about 0.001 Pa to about 100 Pa, from about 0.001 Pa to about 10 Pa, from about 0.01 Pa to about 10 Pa, from about 0.01 Pa to about 1 Pa, from about 0.05 Pa to about 1 Pa, from about 0.05 Pa to about 0.1 Pa, or any range or subrange therebetween. In still further embodiments, the environment (e.g., oxygen-containing environment) can contain one or more inert gases (e.g., argon, xenon, krypton). In yet further embodiments, the environment can consist essentially of oxygen and one or more of argon, xenon, or krypton.

In some embodiments, the sputtering can be conducted with the substrate 103 and/or the sputtering chamber 403 at a temperature of about 20° C. or more, about 30° C. or more, about 80° C. or more, about 400° C. or less, about 300° C. or less, about 200° C. or less, or about 100° C. In some embodiments, the sputtering can be conducted with the substrate 103 and/or the sputtering chamber 403 at a temperature in a range from about 20° C. to about 400° C., from about 30° C. to about 400° C., from about 30° C. to about 300° C., from about 80° C. to about 300° C., from about 80° C. to about 200° C., from about 80° to about 100° C., or any range or subrange therebetween.

In some embodiments, sputtering can comprise a magnetron using strong electric and magnetic fields to direct charged particles (e.g., plasma, ions of the materials comprising the environment (e.g., argon, krypton, xenon, oxygen)) at the sputtering surface 409a, 409b. In further embodiments, the magnetron can comprise a direct current (DC) power source. In even further embodiments, the DC magnetron sputtering may be pulsed (e.g., pulsed reactive sputtering). In even further embodiments, ejection of material from the elemental targets 407a and 407b can be alternated between the elemental targets 407a and 407b as the power to the magnetron (e.g., one or more magnetrons) is pulsed. In further embodiments, operating the magnetron can comprise alternating current (AC) between an anode and cathode that can comprise a frequency (e.g., radio frequency (RF)) of about 13.56 megahertz (MHz), although other frequencies are possible). In some embodiments, the elemental targets 407a, 407b can be rotated relative to the substrate 103. It is to be understood that the parameters such as the energy, the flow of charged particles, and/or the oxygen partial pressure can be based on, for example, the volume of the sputtering chamber 403, the pressure of the sputtering chamber 403, the size of the elemental targets 407a, 407b, the orientation of the elemental targets 407a, 407b, and/or the distance of the substrate from the elemental targets 407a, 407b. In addition to the above considerations, it is to be understood that the thickness of the deposited oxide layer can be controlled by the rate of material ejected from the elemental targets 407a, 407b and the duration of the sputtering process.

As discussed above, the oxide layer 113 deposited on the first major surface can comprise the thickness 119 of the oxide layer 113 and the atomic ratio of the oxygen to the first element. In some embodiments, the thickness 119 of the oxide layer 113 can be in one or more of the ranges discussed above for the thickness 119 of the oxide layer 113. In some embodiments, the atomic ratio of the oxygen to the first element of the oxide layer 113 can be within one or more of the ranges discussed above for the oxide layer 113. Without wishing to be bound by theory, the atomic ratio can increase as the thickness of the oxide layer increases. Consequently, in some embodiments, limiting the thickness of the oxide layer (e.g., about 40 μm or less, about 30 μm or less) can limit the atomic ratio of the oxide ratio, which can promote adhesion between the substrate 103 and the oxide layer 113. In some embodiments, another method (e.g., chemical vapor deposition (CVD) (e.g., low-pressure CVD, plasma-enhanced CVD), physical vapor deposition (PVD) (e.g., evaporation, sputtering, molecular beam epitaxy, ion plating), atomic layer deposition (ALD), spray pyrolysis, chemical bath deposition, sol-gel deposition) may be used to form the oxide layer 113.

After step 303, methods can proceed to step 305 comprising depositing a metallic layer 123 over the oxide layer 113 to produce the laminate 601 shown in FIG. 6. In some embodiments, the metallic layer 123 can be deposited using a single step, for example, using sputtering. In some embodiments, the metallic layer 123 can be deposited using more than one step, for example, two steps or more. In further embodiments, an initial portion of the metallic layer 123 can be deposited with an initial thickness using a first method before using a second method to deposit the rest of the metallic layer. In even further embodiments, the initial thickness can be about 10 nm or more, about 50 nm or more, about 100 nm or more, about 300 nm or more, about 2 μm or less, about 1 μm or less, or about 700 nm or less. In even further embodiments, the initial thickness can be in a range from about 10 nm to about 2 μm to about 50 nm to about 2 μm, from about 50 nm to about 1 μm, from about 100 nm to about 1 μm, from about 100 nm to about 700 nm, from about 300 nm to about 700 nm, or any range or subrange therebetween. In even further embodiments, the initial thickness can be deposited using sputtering (e.g., in an inert environment), although another method (e.g., chemical vapor deposition (CVD) (e.g., low-pressure CVD, plasma-enhanced CVD), physical vapor deposition (PVD) (e.g., evaporation, molecular beam epitaxy, ion plating), atomic layer deposition (ALD), spray pyrolysis, chemical bath deposition, sol-gel deposition) may be used. In even further embodiments, a second method can comprise electroplating and/or electroless plating (e.g., dip coating). In some embodiments, the metallic thickness 129 of the metallic layer 123 can comprise a thickness within one or more of the ranges discussed above for the metallic thickness 129. In further embodiments, the metallic layer 123 can comprise one or more of the materials (e.g., copper) discussed above for the metallic layer 123.

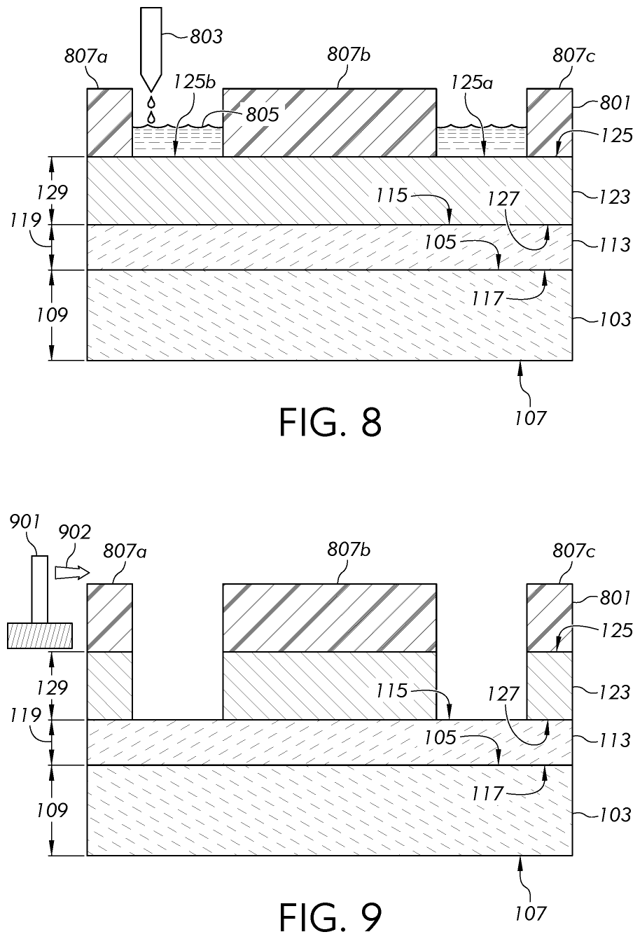

After step 305, the method can proceed to step 307 comprising depositing a mask layer over one or more portions of the metallic layer 123. In some embodiments, the mask can comprise a photoresist formed using photolithography. In some embodiments, as shown in FIG. 7, step 307 can comprise depositing a first liquid 701 over one or more portions of the metallic layer 123. In further embodiments, although not shown, a container (e.g., conduit, flexible tube, micropipette, or syringe) may be used to deposit the first liquid 701 over one or more portions of the metallic layer 123. In further embodiments, as shown, the first liquid 701 can be disposed over the fifth surface area 125 of the metallic layer 123. In further embodiments, as shown in FIG. 7, portions of the first liquid 701 can be cured using radiation 705 (e.g., ultraviolet (UV) light, visible light) to form the mask. In even further embodiments, as shown, portions of the first liquid 701 that are not be cured can be shielded from the radiation using patterned radiation-blocking material 703a, 703b. As shown in FIGS. 7-8, the portion of the first liquid 701 exposed to radiation can form a mask portion 807a, 807b, or 807c of the mask layer 801. In some embodiments, another method (e.g., chemical vapor deposition (CVD) (e.g., low-pressure CVD, plasma-enhanced CVD), physical vapor deposition (PVD) (e.g., evaporation, molecular beam epitaxy, ion plating), atomic layer deposition (ALD), sputtering, spray pyrolysis, chemical bath deposition, sol-gel deposition) may be used to form the mask (e.g., mask layer 801 comprising mask portions 807a, 807b, 807c). As shown in FIG. 8, the result of step 307 can comprise a mask layer 801 comprising mask portions 807a, 807b, 807c disposed over the fifth surface area 125 of the metallic layer 123. In further embodiments, as shown in FIG. 8, the mask layer 801 comprising mask portions 807a, 807b, 807c can contact portions of the fifth surface area 125 of the metallic layer 123. In some embodiments, a material of the mask can comprise a photocurable resin (e.g., polymeric material). In some embodiments, forming the mask layer 801 can comprise heating the first liquid 701 and/or the mask layer 801 during step 307.

After step 307, as shown in FIG. 8, methods can proceed to step 309 comprising etching at least a portion of the metallic layer 123 after depositing the mask layer 801. In some embodiments, as shown, the portions 125a, 125b of the fifth surface area 125 of the metallic layer 123 can correspond to portions of the fifth surface area 125 not covered (e.g., contacted) by the mask layer 801. In some embodiments, as shown, etching can comprise exposing at least a portion 125a, 125b of the fifth surface area 125 of the metallic layer 123 to an etchant 805. In further embodiments, as shown, the etchant 805 can be a liquid etchant contained in an etchant bath defined by the portions 807a, 807b, 807c of the mask layer 801. The etchant bath can be provided by filling areas between the portions 807a, 807b, 807c with etchant from a container 803 (e.g., conduit, flexible tube, micropipette, or syringe). In even further embodiments, the etching solution can comprise one or more mineral acids (e.g., HCl, HF, H₂SO₄, HNO₃) and/or another material (e.g., iron chloride). In some embodiments, the etchant 805 can comprise a temperature of about 20° C. or more, about 50° C. or more, about 100° C. or less, about 80° C. or less, or about 30° C. or less. In some embodiments, the etchant 805 can comprise a temperature in a range from about 20° C. to about 100° C., from about 50° C. to about 100° C., from about 50° C. to about 80° C., or from about 20° C. to about 30° C., or any range or subrange therebetween. In some embodiments, the etchant 805 can contact the laminate for about 1 second or more, about 10 seconds or more, about 30 seconds or more, about 1 minute or more, about 3 minutes or more, about 30 minutes or less, about 15 minutes or less, about 10 minutes or less, or about 5 minutes or less. In some embodiments, the etchant 805 can contact the laminate for a time in a range from about 1 second to about 15 minutes, from about 10 seconds to about 15 minutes, from about 10 seconds to about 10 minutes, from about 30 seconds to about 10 minutes, from about 30 seconds to about 5 minutes, from about 1 minute to about 5 minutes, from about 3 minutes to about 5 minutes, or any range or subrange therebetween. In some embodiments, the etchant can be selected based on a selectivity between an etching rate of the metallic layer and an etching rate of the oxide layer.

After step 309, as shown in FIG. 9, methods can proceed to step 311 comprising removing the mask layer 801 after the etching in step 309. In some embodiments, as shown in FIG. 9, removing the mask layer 801 (e.g., mask portions 807a, 807b, 807c) can comprise moving a tool 901 in a direction 902 across the surface (e.g., fifth surface area 125) of the metallic layer 123. In even further embodiments, using the tool may comprise sweeping, scraping, grinding, pushing, etc. In further embodiments, the mask layer 801 (e.g., mask portions 807a, 807b, 807c) can be removed by washing the surface (e.g., fifth surface area 125) of the metallic layer 123 with a solvent.

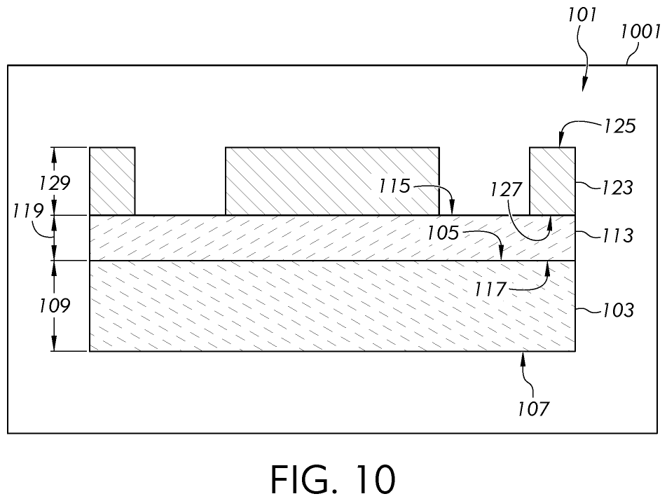

After step 303, 305, or 311, as shown in FIG. 10, methods of the disclosure can proceed to step 313 comprising heating the laminate 101 at a first temperature for a first period of time. In some embodiments, as shown, the laminate 101 can be placed in an oven 1001 maintained at the first temperature. In further embodiments, the first temperature can be about 250° C. or more, about 275° C. or more, about 300° C. or more, about 325° C. or less, about 400° C. or less, or about 375° C. or less, or about 350° C. or less. In some embodiments, the first temperature can be in a range from about 250° C. to about 400° C., from about 275° C. to about 400° C., from about 275° C. to about 375° C., from about 300° C. to about 375° C., from about 325° C. to about 375° C., from about 325° C. to about 350° C., or any range or subrange therebetween. In some embodiments, the first time can be about 15 minutes or more, about 30 minutes or more, about 45 minutes or more, about 1 hour or more, about 6 hours or less, about 4 hours or less, or about 3 hours or less, or about 1.5 hours or less. In some embodiments, the first time can be in a range from about 15 minutes to about 6 hours, from about 30 minutes to about 6 hours, from about 30 minutes to about 4 hours, from about 45 minutes to about 4 hours, from about 45 minutes to about 3 hours, from about 1 hour to about 3 hours, from about 1 hour to about 1.5 hours, or any range or subrange therebetween. Heating the laminate at a first temperature of about 250° C. or more promotes a decrease in the oxygen content (e.g., a decrease in the atomic ratio of oxygen to the first element), which can enable increased adhesion (e.g., peel strength) between the oxide layer and the substrate. Heating the laminate at a first temperature of about 400° C. or less promotes a decrease in the oxygen content (e.g., a decrease in the atomic ratio of oxygen to the first element) without significant crystallization or other changes in the laminate that may be detrimental to properties of the laminate.

After step 301, 311, or 313, methods of the disclosure can proceed to step 315. In some embodiments, step 315 may comprise the beginning of a subsequent process. In further embodiments, step 315 can comprise storing the laminate for future assembly in an application and/or further processing. In some embodiments, step 315 can comprise assembling the laminate in an application (e.g., a display application, an electronic device), as discussed above. In some embodiments, methods of the disclosure can be complete upon reaching step 315. In some embodiments, methods of the disclosure according to the flow chart in FIG. 3 of making the foldable apparatus can be complete at step 315.

In some embodiments, methods of making a foldable apparatus in accordance with embodiments of the disclosure can proceed along steps 301, 303, 305, 307, 309, 311, 313, and 315 of the flow chart in FIG. 3 sequentially, as discussed above. In some embodiments, as shown in FIG. 3, arrow 304 can be followed from step 303 to step 313 comprising heating the laminate comprising the oxide coating, for example, if the laminate does not comprise a metallic layer or if a metallic layer is to be deposited in further processing of the laminate. In some embodiments, arrow 310 can be followed from step 305 to step 313 comprising heating the laminate comprising the oxide coating, for example, if the laminate comprises a continuous metallic layer or if a metallic layer is to be patterned (e.g., etched) in further processing of the laminate. In some embodiments, methods can follow arrow 302 from step 303 to step 315, for example, if the laminate is fully assembled at the end of step 303 or step 315. In some embodiments, methods can follow arrow 308 from step 305 to step 315, for example, if the laminate is fully assembled at the end of step 305 or step 315. In some embodiments, methods can follow arrow 306 from step 311 to step 315, for example, if the laminate is fully assembled at the end of step 311 or step 315. Any of the above options may be combined to make a foldable apparatus in accordance with embodiments of the disclosure.

### EXAMPLES

Various embodiments will be further clarified by the following examples. The properties of the oxide layer and resulting peel strength of the laminate of Examples A-H are presented in Tables 1-2. Examples A-H comprise a substrate comprising a glass material (Composition 1 having a nominal composition in mol % of 63.6 SiO₂; 15.7 Al₂O₃; 10.8 Na₂O; 6.2 Li₂O; 1.16 ZnO; 0.04 SnO₂; and 2.5 P₂O₅), a substrate thickness of 150 μm, and a surface roughness (Ra) of 0.3 nm. For each example, 35 samples were prepared and measured to determine the reported peel strength and/or atomic ratio. In Examples A-H, the oxide layer consisted of titanium oxide with the thickness of the oxide layer presented in Tables 1-2 was deposited on the first major surface of the substrate. In Examples A-H, a metallic layer consisting of copper comprising a metallic thickness of 12 μm was deposited on the oxide layer by sputtering a 500 nm layer of copper followed by electroplating. Examples A-G did not comprise a heat treatment. In Examples A-G, the oxide layer was deposited using pulsed DC reactive sputtering with a magnetron pulsed at 10 kHz with a duty cycle of 50% to sputter titanium from an elemental target comprising a diameter of 100 millimeters (mm) at 100° C. with a partial pressure of oxygen maintained at 500 Pa. In Example H, the oxide layer was deposited using DC reactive sputtering with a magnetron pulsed at 10 kHz with a duty cycle of 50% to sputter titanium dioxide (TiO₂) from a target consisting of TiO₂ comprising a diameter of 100 mm at 100° C. in an inert environment comprising argon.

The peel strength for Examples A-E is presented in Table 1. For Examples A-C, the peel strength increases with thickness of the oxide layer going from 10 nm to 30 nm corresponding to peel strengths from 2.82 N/cm to 5.68 N/cm. Further increasing the thickness of the oxide layer beyond 30 nm (Examples D-E) is associated with a decrease in the peel strength from 5.68 N/cm at 30 nm to 1.68 N/cm at 40 nm and 1.62 N/cm at 1.36 N/cm. Increasing the thickness of the oxide layer to 100 nm produces a high variability of the peel strength.

TABLE 1
Properties of Examples A-E

| | Oxide Layer | Peel Strength |
|---|---|---|
| Example | Thickness (nm) | (N/cm) |
| A | 10 | 2.82 |
| B | 20 | 4.40 |
| C | 30 | 5.68 |
| D | 40 | 1.62 |
| E | 50 | 1.36 |
| F | 100 | N/A |

TABLE 2
Atomic Ratio and Peel Strength for Examples C, E, and G-H

| | Oxide Layer | Peel Strength | Atomic ratio |
|---|---|---|---|
| Example | Thickness (nm) | (N/cm) | O/Ti |
| H | 30 | 0.20 | 2.00 |
| E | 50 | 1.36 | 1.38 |
| C | 30 | 5.68 | 0.74 |
| G | 30 | 6.80 | 0.37 |

The atomic ratios of Examples C and E-H and peel strengths are presented in Table 2. The atomic ratio of oxygen to titanium of the oxide layer was measured using transmission electron microscope (TEM) energy dispersive X-ray spectroscopy (EDS). Example H comprised an atomic ratio of 2.00 (formed by sputtering from a TiO₂ target rather than an elemental titanium target) and peel strength of 0.20 N/cm. Decreasing the atomic ratio to 1.38 (Example E) is associated with an increase in the peel strength to 1.36 N/cm. Further decreasing the atomic ratio to 0.74 (Example C) is associated with a further increase in the peel strength to 5.68 N/cm. Consequently, decreasing the atomic ratio of oxygen to titanium increases, especially below about 1.50. Further, reactive sputtering from an elemental titanium target in an oxygen-containing environment can produce lower atomic ratios and greater adhesion than sputtering from a TiO₂ target.

Of Examples A-F, Example C comprising a thickness of the oxide layer of 30 nm has the greatest peel strength (5.68 N/cm). Example H comprises the laminate of Example C that was further heat treated in an oven at 350° C. for 1 hour. The heat treatment decreased the atomic ratio from 0.74 (Example C) to 0.37 (Example G) while increasing the peel strength from 5.68 N/cm (Example C) to 6.80 N/cm (Example G). Consequently, heating the laminate can further decrease the atomic ratio of the oxide layer and increase the peel strength of the laminate.

Embodiments of the disclosure can provide laminates with good adhesion between a substrate and an oxide layer. Providing an oxide layer comprising oxygen and a first element with a limited atomic ratio of oxygen to the first element (e.g., about 1.5 or less, about 1 or less, about 0.8 or less) can enable good adhesion. In some embodiments, providing a non-stoichiometric ratio of oxygen to the first element can further promote adhesion. Limiting the thickness of the oxide layer (e.g., about 40 nm or less, about 30 nm or less) can enable good adhesion, for example, by limiting the oxygen content of the oxide layer. In some embodiments, a substrate comprising glass and/or ceramic can have good adhesion with the oxide layer, for example, with covalent bonding or polar interactions. In further embodiments, the first element in the oxide layer can comprise at least one of titanium, tantalum, silicon, or aluminum, which can promote adhesion with a substrate comprising glass and/or ceramic.

In some embodiments, the laminate can comprise a metallic layer disposed over the oxide layer. Providing a metallic layer can enable good adhesion between the metallic layer and the oxide layer. In further embodiments, adhesion between the metallic layer and the oxide layer can be greater than the adhesion between the oxide layer and the substrate. For example, the metallic layer can comprise copper, which has negative mixing enthalpy with titanium in an oxide layer comprising titanium oxide, providing strong adhesion between the metallic layer and the oxide layer. In further embodiments, the metallic layer can be electrically conductive and patterned to form a discontinuous layer over the first major surface of the substrate, which can serve as wiring connections, for example, as part of the circuit board. In even further embodiments, the oxide layer can be electrically non-conductive, which can electrically isolate discontinuous portions of the metallic layer from one another.

Embodiments of the disclosure can provide methods of making a laminate comprising depositing an oxide layer over a substrate using reactive sputtering from an elemental target in an oxygen-containing environment, which can enable control of the oxygen content of the resulting oxide layer and promote adhesion between the substrate and the oxide layer. In some embodiments, a metallic layer (e.g., electrically conductive) can be disposed on the oxide layer (e.g., electrically non-conductive) and patterned to be discontinuous over a first major surface without removing corresponding portions of the discontinuous metallic layer, which can simplify processing of the laminate, for example, by reducing processing time and overall cost to make the laminate.

As used herein, the terms “the,” “a,” or “an,” mean “at least one,” and should not be limited to “only one” unless explicitly indicated to the contrary. Thus, for example, reference to “a component” comprises embodiments having two or more such components unless the context clearly indicates otherwise.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an endpoint of a range, the disclosure should be understood to comprise the specific value or endpoint referred to. If a numerical value or endpoint of a range in the specification recites “about,” the numerical value or endpoint of a range is intended to comprise two embodiments: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In some embodiments, “substantially similar” may denote values within about 10% of each other, for example within about 5% of each other, or within about 2% of each other.

As used herein, the terms “comprising” and “including,” and variations thereof, shall be construed as synonymous and open-ended, unless otherwise indicated. A list of elements following the transitional phrases comprising or including is a non-exclusive list, such that elements in addition to those specifically recited in the list may also be present.

While various embodiments have been described in detail with respect to certain illustrative and specific embodiments thereof, the present disclosure should not be considered limited to such, as numerous modifications and combinations of the disclosed features are possible without departing from the scope of the following claims.

1. A laminate comprising:
a substrate comprising a first major surface; and
an oxide layer disposed over the first major surface of the substrate, the oxide layer comprising a thickness of about 40 nanometers or less, the oxide layer comprising oxygen and a first element, the first element comprising at least one of titanium, tantalum, silicon, or aluminum, and the oxide layer further comprising an atomic ratio of the oxygen to the first element of about 1.5 or less,
wherein a peel strength of the laminate between the substrate and the oxide layer, measured at 20° C. in accordance with IPC-TM-650.2.4.8 Condition A, is about 1.3 Newtons per centimeter or more.

2. The laminate of claim 1, further comprising a metallic layer disposed over the oxide layer.

3. The laminate of claim 2, wherein the metallic layer comprises copper.

4. The laminate of claim 2, wherein the metallic layer comprises a thickness in a range from 100 nanometers to about 20 micrometers.

5. (canceled)

6. The laminate of claim 2, wherein the metallic layer directly contacts the oxide layer.

7. The laminate of claim 2, wherein the metallic layer is discontinuous over the first major surface of the substrate.

8. The laminate of claim 7, wherein the oxide layer is substantially continuous over the first major surface of the substrate.

9. The laminate of claim 1, wherein the atomic ratio of the oxygen to the first element is 0.8 or less.

10. The laminate of claim 1, wherein the oxide layer comprises titanium oxide, the first element comprises titanium, and an atomic ratio of the oxygen to the titanium is 1.5 or less.

11. The laminate of claim 10, wherein the atomic ratio of the oxygen to the titanium of the titanium oxide is 0.8 or less.

12. The laminate of claim 1, wherein the oxide layer consists essentially of titanium oxide.

13. The laminate of claim 1, wherein the oxide layer is electrically non-conductive.

14. (canceled)

15. The laminate of claim 1, wherein the oxide layer directly contacts the first major surface of the substrate.

16. The laminate of claim 1, wherein the peel strength of the laminate between the substrate and the oxide layer is in a range from about 2.5 Newtons per centimeter to about 7 Newtons per centimeter.

17.-19. (canceled)

20. The laminate of claim 1, wherein the substrate comprises a thickness in a range from about 25 micrometers to about 2 millimeters.

21. (canceled)

22. A method of making a laminate comprising:
depositing an oxide layer over a first major surface of a substrate by sputtering from an elemental target comprising a first element in an oxygen-containing environment, the oxide layer comprising a thickness of about 40 nanometers or less, the oxide layer comprising oxygen and the first element, the first element comprising at least one of titanium, tantalum, silicon, or aluminum, and the oxide layer further comprising an atomic ratio of the oxygen to the first element of 1.5 or less,
wherein a peel strength of the laminate between the substrate and the oxide layer, measured at 20° C. in accordance with IPC-TM-650.2.4.8 Condition A, is about 1.3 Newtons per centimeter or more.

23. The method of claim 22, further comprising depositing a metallic layer over the oxide layer.

24. The method of claim 23, further comprising:
depositing a mask layer with a predetermined pattern on the metallic layer;
etching at least a portion of the metallic layer after depositing the mask layer; and
removing the mask layer after the etching.

25. The method of claim 23, wherein the metallic layer is discontinuous over a footprint of the first major surface of the substrate, and the oxide layer is substantially continuous over the footprint of the first major surface of the substrate.

26.-27. (canceled)

28. The method of claim 22, wherein the metallic layer directly contacts the oxide layer.

29. The method of claim 22, further comprising heating the laminate at a temperature in a range from about 250° C. to about 400° C. for a time in a range from about 15 minutes to about 6 hours.

30. The method of claim 22, wherein the atomic ratio of the oxygen to the first element is 0.8 or less.

31. The method of claim 22, wherein the oxide layer comprises titanium oxide, the first element comprises titanium, and an atomic ratio of the oxygen to the titanium is 1.5 or less.

32. The method of claim 31, wherein the atomic ratio of the oxygen to the titanium of the titanium oxide is 0.8 or less.

33. The method of claim 22, wherein the oxide layer consists essentially of titanium oxide.

34.-41. (canceled)
